(19) United States
(12) Patent Application Publication
(10) Pub. No.: US 2022/0172165 A1
(43) Pub. Date: Jun. 2, 2022

(54) COMPLIANT AND SUSTAINABLE PRODUCT DESIGN

(71) Applicant: SAP SE, Walldorf (DE)

(72) Inventors: Pallavi Dhakne, San Jose, CA (US); Kangle Ruan, Shanghai (CN); BoYi Zhang, Vancouver (CA); Akash Kumar, Bangalore (IN); Anahita Minuchaher Havewala, Bangalore (IN)

(21) Appl. No.: 17/107,377

(22) Filed: Nov. 30, 2020

(51) Int. Cl. G06Q 10/08; G06F 30/20

(52) U.S. Cl. CPC G06Q 10/0875; G06F 30/20

(57) ABSTRACT

A product design system may analyze a bill of materials to determine compliance (e.g., regulatory) information for one or more regions and sustainability information (e.g., carbon emissions, usage of recycled materials, end product recyclability, water usage, energy usable, etc.). A product design score may be determined from this information based one weights for each of the parameters. The product designer may also be provided with a user interface for replacing materials with available options. In addition, the product design system may perform a cost-benefit analysis for the different material options based on potential conversion of environmentally conscious consumers. Estimated risks and estimated financial losses based on non-compliance may also be determined and presented in the user interface.

### BACKGROUND

The present disclosure pertains to product design and in particular to assessing compliance and sustainability in product design.

When designing a product, a product designer may be constrained by their customer's needs and budget. Often there are different choices of materials that may be used to manufacture the product. Typically, product designers will select a material that is cheaper and readily available to the manufacturing plant as compared to others, in order to meet the customer's needs and budget. Once the designer has finalized the materials, a bill of materials (BOM) for the design may be sent to a production unit for the manufacturing of the product. However, it may later be determined that certain materials in the BOM are not compliant with the laws and regulations for a particular region or country, which may be the product's target customers' region. This problem may have occurred because the product designer did not know the government regulations for each material and its compliance status.

The underlying problem of the invention is that the designer does not have a compliance report of materials in each region. The product designer also does not have insights about the revenue or market share/customer impact of selecting one material over the other. It might be the case that the customers are willing to pay higher prices if the product is greener—which would offset the increased cost of the material, and might convert some leads into new customers, thus improving market share.

The present disclosure addresses these issue and others, as further described below.

### SUMMARY

One embodiment provides a computer system comprising one or more processors. The computer system further comprises one or more machine-readable medium coupled to the one or more processors and storing computer program code. The computer program code comprises sets instructions executable by the one or more processors to obtain a bill of materials from a client computer including a plurality of materials for manufacturing a product. The computer program code further comprises sets instructions executable by the one or more processors to determine material compliance information for a set of regions and sustainability information for the plurality of materials. The computer program code further comprises sets instructions executable by the one or more processors to determine a compliance score using the material compliance information. The compliance score based on whether each material of the plurality of materials is compliant for each region of the set of regions. The computer program code further comprises sets instructions executable by the one or more processors to determine one or more sustainability scores using the sustainability information for the plurality of materials. The computer program code further comprises sets instructions executable by the one or more processors to determine a first product design score based on the compliance score, a weight for the compliance score, the one or more sustainability scores, and one or more weights for the one or more sustainability scores. The computer program code further comprises sets instructions executable by the one or more processors to provide a product design report to the client computer for presentation in a user interface of the client computer, the product design report including the plurality of materials, a compliance status for each of the plurality of materials, and the product design score.

Another embodiment provides one or more non-transitory computer-readable medium storing computer program code. The computer program code comprises sets of instructions to obtain a bill of materials from a client computer including a plurality of materials for manufacturing a product. The computer program code further comprises sets of instructions to determine material compliance information for a set of regions and sustainability information for the plurality of materials. The computer program code further comprises sets of instructions to determine a compliance score using the material compliance information. The compliance score based on whether each material of the plurality of materials is compliant for each region of the set of regions. The computer program code further comprises sets of instructions to determine one or more sustainability scores using the sustainability information for the plurality of materials. The computer program code further comprises sets of instructions to determine a first product design score based on the compliance score, a weight for the compliance score, the one or more sustainability scores, and one or more weights for the one or more sustainability scores. The computer program code further comprises sets of instructions to provide a product design report to the client computer for presentation in a user interface of the client computer, the product design report including the plurality of materials, a compliance status for each of the plurality of materials, and the product design score.

Another embodiment provides a computer-implemented method. The method comprises obtaining a bill of materials from a client computer including a plurality of materials for manufacturing a product. The method further comprises determining material compliance information for a set of regions and sustainability information for the plurality of materials. The method further comprises determining a compliance score using the material compliance information. The compliance score based on whether each material of the plurality of materials is compliant for each region of the set of regions. The method further comprises determining one or more sustainability scores using the sustainability information for the plurality of materials. The method further comprises determining a first product design score based on the compliance score, a weight for the compliance score, the one or more sustainability scores, and one or more weights for the one or more sustainability scores. The method further comprises providing a product design report to the client computer for presentation in a user interface of the client computer, the product design report including the plurality of materials, a compliance status for each of the plurality of materials, and the product design score.

The following detailed description and accompanying drawings provide a better understanding of the nature and advantages of the present disclosure.

### BRIEF DESCRIPTION OF THE DRAWINGS

FIG. 1 shows a diagram of product design system in communication with a client computer and a database server, according to an embodiment.

FIG. 2 shows an exemplary user interface presenting a bill of materials, a non-compliant material, and a design score, according to an embodiment.

FIG. 3 shows an exemplary user interface presenting a list of replacement materials, according to an embodiment.

FIG. 4 shows an exemplary user interface presenting a bill of compliant materials and a design score, according to an embodiment.

FIG. 5 shows a flowchart of a method for determining a product design score, according to an embodiment.

FIG. 6 shows a flowchart of a process for determining compliance of a bill of materials and replacing materials, according to an embodiment.

FIG. 7 shows a diagram of components of a product design system and a user interface for the product design system, according to an embodiment.

FIG. 8 shows a diagram of hardware of a special purpose computing machine for implementing systems and methods described herein.

### DETAILED DESCRIPTION

In the following description, for purposes of explanation, numerous examples and specific details are set forth in order to provide a thorough understanding of the present disclosure. Such examples and details are not to be construed as unduly limiting the elements of the claims or the claimed subject matter as a whole. It will be evident, based on the language of the different claims, that the claimed subject matter may include some or all of the features in these examples, alone or in combination, and may further include modifications and equivalents of the features and techniques described herein.

In the figures and their corresponding description, while certain elements may be depicted as separate components, in some instances one or more of the components may be combined into a single device or system. Likewise, although certain functionality may be described as being performed by a single element or component within the system, the functionality may in some instances be performed by multiple components or elements working together in a functionally coordinated manner. In addition, hardwired circuitry may be used independently or in combination with software instructions to implement the techniques described in this disclosure. The described functionality may be performed by custom hardware components containing hardwired logic for performing operations, or by any combination of computer hardware and programmed computer components. The embodiments described in this disclosure are not limited to any specific combination of hardware circuitry or software. The embodiments can also be practiced in distributed computing environments where operations are performed by remote data processing devices or systems that are linked through one or more wired or wireless networks. As used herein, the terms “first,” “second,” “third,” “fourth,” “fifth,” “sixth,” “seventh,” “eighth,” “ninth,” “tenth,” etc., do not necessarily indicate an ordering or sequence unless indicated. These terms, as used herein, may simply be used for differentiation between different objects or elements.

As mentioned above, when designing a product, a product designer may be constrained by their customer's needs and budget. Often there are different choices of materials that may be used to manufacture the product. Typically, product designers will select a material that is cheaper and readily available to the manufacturing plant as compared to others, in order to meet the customer's needs and budget. Once the designer has finalized the materials, a bill of materials (BOM) for the design may be sent to a production unit for the manufacturing of the product. However, it may later be determined that certain materials in the BOM are not compliant with the laws and regulations for a particular region or country, which may be the product's target customers' region. This problem may have occurred because the product designer did not know the government regulations for each material and its compliance status.

One of the underlying problems is that the product designer does not have a compliance report of materials in each region. The product designer also may not have insight about the revenue or market share/customer impact of selecting one material over the other.

Features and advantages of the present disclosure include configuring a product design system to generate a compliance report for materials in a bill of materials for a product. The compliance report may indicate compliance of each material in a set of regions in which the product will be such. As such, product designers may know the compliance status of the materials at design time, thereby avoiding the delays and costs of redesigning the product.

Furthermore, certain customers or potential customers may be willing to pay higher prices if the product is “greener” (more environmentally sustainable), which may offset any increased cost of the more sustainable materials. Providing a more environmentally sustainable product may leads to new environmentally conscious customers, thereby improving market share.

Features and advantages of the present disclosure include configured a product design system to generate a market share impact report based on environmentally conscious segments of the market being converted to potential customers, and configuring the product design system to determine estimated risks and financial losses that may occur a result of fines or penalties due to non-compliant materials. From these reports, the product designer may be provided with sufficient information to select materials that are not only more environmentally sustainable, but also materials that reduce risks and increase estimated profits.

The product design system, which is described in further detail below, may provide a product design score based on material compliance and environmental sustainability. The product design system may also generate a material compliance report. The product design system may also determine cost-benefit and brand value insights and present these to the product designer during the design phase such that products with “greener,” more environmentally sustainable designs may be manufactured.

The product design system enables product designers to upload bills of materials for different products. The product design system is configured to generate and display environmental compliance report listing the non-compliant materials in different regions (e.g., countries or states) where the product will be manufactured or sold. The product design system may provide a compliance score for each material and corresponding compliance information, such as the different laws and regulations. The product design system may also give the user an option to swap the non-compliant material with a compliant one. The product design system is further configured to calculates a product design score (which may be referred to as a “green score”) based on the compliance score, how sustainably the material is sourced or procured, the carbon footprint for extraction, the usage of recycled material, the recyclability of the end product, the water used, the total energy used, and other similar measures of product design measure, for example. The product design system may also provide cost-benefit analysis including detailed insights on how it will impact sales and revenue by including various factors including a market share impact report based on environmentally conscious segments of the market being converted to potential customers, and further including estimated risks and financial losses that may occur as a result of fines or penalties due to non-compliant materials. The product design system is described in further detail below.

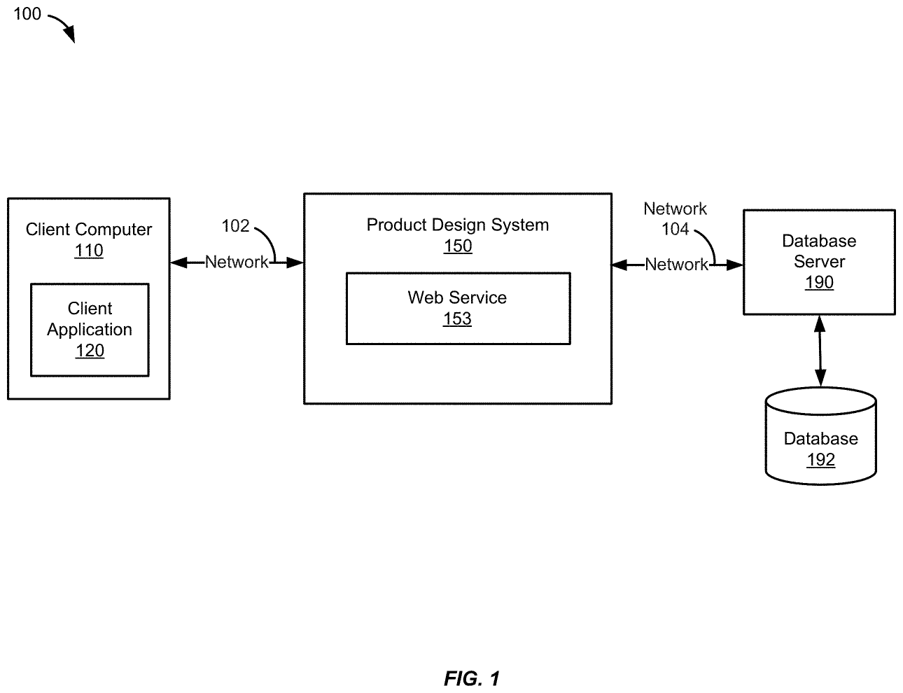

FIG. 1 shows a diagram of product design system 150 in communication with a client computer 110 and a database server 190, according to an embodiment. The client computer system 110 may be a personal computer, a laptop, a smart phone, or a tablet, for example. The client computer 110 may be configured to execute a client application 120. The client application 120 may be a web browser or other web-based application stored locally on the client computer 110. The client application 120 may be used to access, interact with, and receive information from the product design system 150, as further described below.

The client computer 110 may communicate with the product design system 150 over a network 102, such as the Internet or an intranet. The product design system 150 may be used to collect, store, and manage data use for analytics. The product design system 150 may be configured to provide a user interface for the client application 120. The user interface may be provided via a web service 153. In some embodiments, the user interface may be provided using a cloud-based computer network architecture. The product design system 150 may be implemented as a computer server or a plurality of computer servers coupled together and working in a functionally coordinated manner.

The product design system 150 may further be in communication with a database server 190 over a network 104, such as the Internet or an intranet. The database server 190 is further in communication with or electronically coupled to database storage 192. In some embodiments, the database server 190 and the database storage 192 are part of the product design system 150. The database server 190 can be configured to perform data accesses operations on data stored in the database 192. The database server 190 may be implemented as a computer server or a plurality of computer servers coupled together and working in a functionally coordinated manner. Depending on the type of database server 190, data operations may range from simple operations, such as storing and retrieving data, to more complex operations such as calculating statistics based on the data, or arranging, modifying, or formatting data.

The database server 190 may further include a database management system (“DBMS”) that communicates with the one or more databases for the purposes of storing and retrieving data to or from the databases. The DBMS may be configured as a computer software application that interacts with the database and other applications or users to capture and analyze data. The DBMS may be designed to allow for definition, creation, querying, update, and administration of databases, for example. A database “query” may comprise a request for data or information from a database table or combination of database tables (or other data structures) in the database. Queries are the mechanism for retrieving information from a database and generally consist of questions presented to the database in a predefined format. This data may be generated as results returned by the SQL, or as pictorials, graphs, etc.

The network 102 and network 104 may be implemented as a single wired or wireless network, or multiple separate networks in communication with one another. For example, the networks described herein can be implemented as a local area network (“LAN”), wide-area network (“WAN”), combination of LANs and WANs, the Internet, for example. Further, the network 102 and 104 may be implemented in a cloud-based network configuration.

As described herein, the client computer 110 may provide a bill of materials for a product to the product design system 150. The product design system 150 may query the database server 190 for compliance

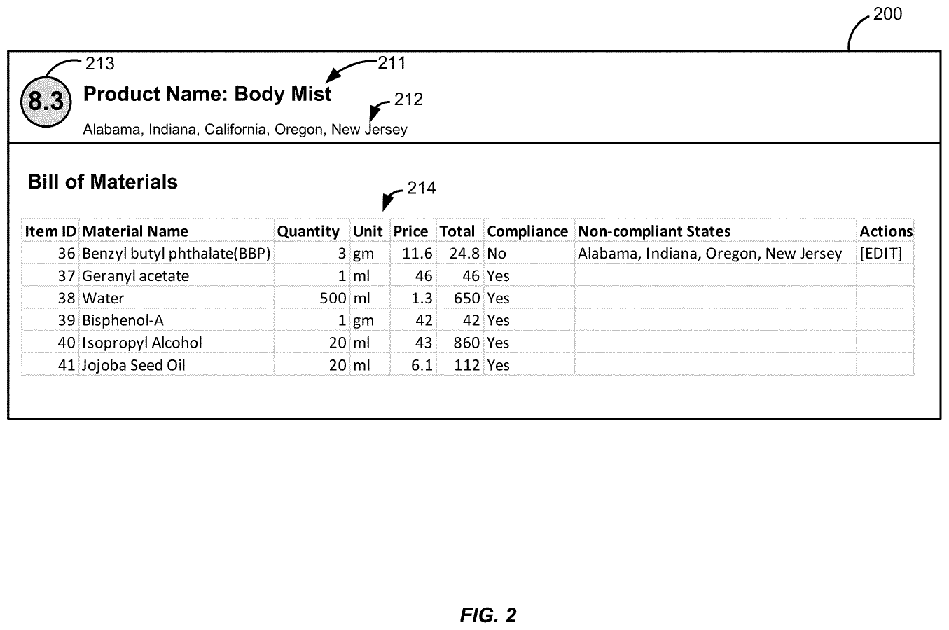

FIG. 2 shows an exemplary user interface 200 presenting a bill of materials 214, a non-compliant material, and a design score 213, according to an embodiment. The information presented in the user interface 200 may be determined or generated by a product design system, as described herein. The user interface 200 may be rendered and presented by a client computer, as described herein.

The user interface 200 shows a bill of materials 214 for a product named “Body Mist” as shown in the title 211. This product may be intended for sale in a plurality of regions as shown in the list of regions 212. In this example, the regions include Alabama, Indiana, California, Oregon, New Jersey.

As shown in FIG. 2, the bill of materials 214 includes Benzyl butyl phthalate(BBP), Geranyl acetate, Water, Bisphenol-A, Isopropyl Alcohol, and Jojoba Seed Oil. In addition, the user interface 200 includes a compliance status indicator for each of the materials. For instance, a compliance status indicator (e.g., “No” in the “Compliance” column) for Benzyl butyl phthalate(BBP) indicate that it is non-compliant for one or more of the plurality of regions. As shown in the “non-compliant states” column, Benzyl butyl phthalate(BBP) is not compliant in Alabama, Indiana, Oregon, and New Jersey. The material Benzyl butyl phthalate(BBP) may be determined to be non-compliant based on compliance information for these regions. The compliance information may include laws or regulations enforced by these regions, for example.

In this example, the product design score 213 is “8.3”. This product design score may be based on the compliance status of each of the materials in the bill of materials 214, and other factors such as how sustainably the material is sourced or procured, the carbon footprint for extraction, the usage of recycled material, the recyclability of the end product, the water used, and the total energy used as further described below. The product design score may be lower when fewer materials in the BOM are compliant and it may be higher when more materials in the BOM are compliant. In this example, the product design score may be in a range of 0 to 10. Other ranges may be used in other embodiments.

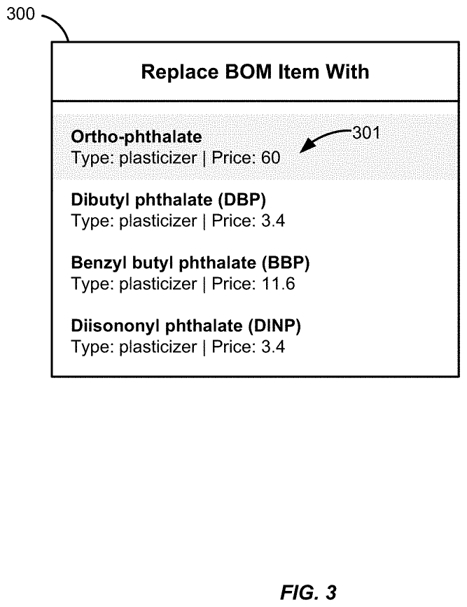

The user interface 200 may also include an option to change materials, such as the non-complaint material. For instance, as shown in FIG. 2 an “EDIT” button may be provided in an “Actions” column of the bill of materials 214. Selecting or clicking on the “EDIT” button may cause a replacement material user interface dialog to be presented as further discussed below with respect to FIG. 3.

FIG. 3 shows an exemplary user interface 300 presenting a list of replacement materials, according to an embodiment. The information presented in the user interface 300 may be determined or generated by a product design system, as described herein. The user interface 300 may be rendered and presented by a client computer, as described herein.

The user interface 300 may be presented after a user selects an edit, change, or modification action for a particular material in the bill of materials shown in FIG. 2. As shown in FIG. 3, the user interface may present replacement materials that may replace the material selected to be edited or changed in the user interface 200 of FIG. 2. In this example, the user interface 300 includes four options: ortho-phthalate, dibutyl phthalate (DBP), benzyl butyl phthalate (the material selected to be replaced), and diisononyl phthalate (DINP). The user interface 300 also indicates a type for each of the replacement materials and a price for each of the replacement materials.

In this example, a user of the client computer (e.g., the product designer) makes selects ortho-phthalate as the replacement material. The selection of ortho-phthalate may be indicated by highlighting 301 of the row for the ortho-phthalate material.

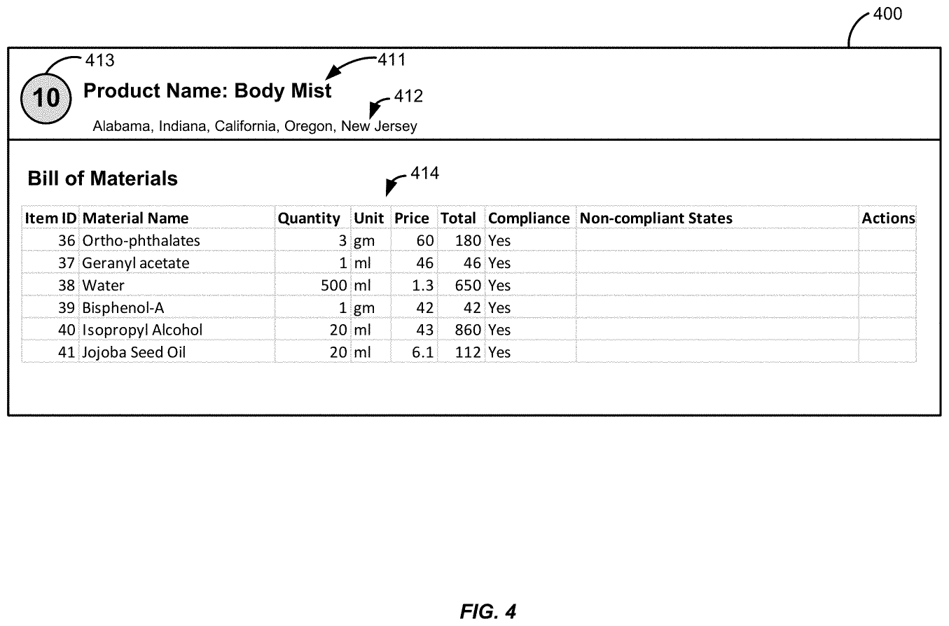

FIG. 4 shows an exemplary user interface 400 presenting a bill of compliant materials 414 and a design score 413, according to an embodiment. The information presented in the user interface 400 may be determined or generated by a product design system, as described herein. The user interface 400 may be rendered and presented by a client computer, as described herein.

The user interface 400 shows updates to the user interface 200 of FIG. 2 after selecting a replacement material as discussed above with respect to FIG. 3. Similar to the user interface 200 of FIGS. 2, the user interface 400 shows a bill of materials 414 for the product named “Body Mist” as shown in the title 411. Similar to the user interface 200 of FIG. 2, this product may be intended for sale in a plurality of regions as shown in the list of regions 412. In this example, the regions include Alabama, Indiana, California, Oregon, New Jersey.

As shown in FIG. 4, the bill of materials 414 does not include Benzyl butyl phthalate (BBP) as it was replaced by ortho-phthalates, as discussed above with respect to FIG. 3. Ortho-phthalates is compliant with the laws and regulations of the sales regions for the product (i.e., Alabama, Indiana, California, Oregon, and New Jersey). Accordingly, the product design score 413 of FIG. 4 has increased from “8.3” (as in FIGS. 2) to “10.” The product design score may also be based on sustainability information for the plurality of materials as further described below.

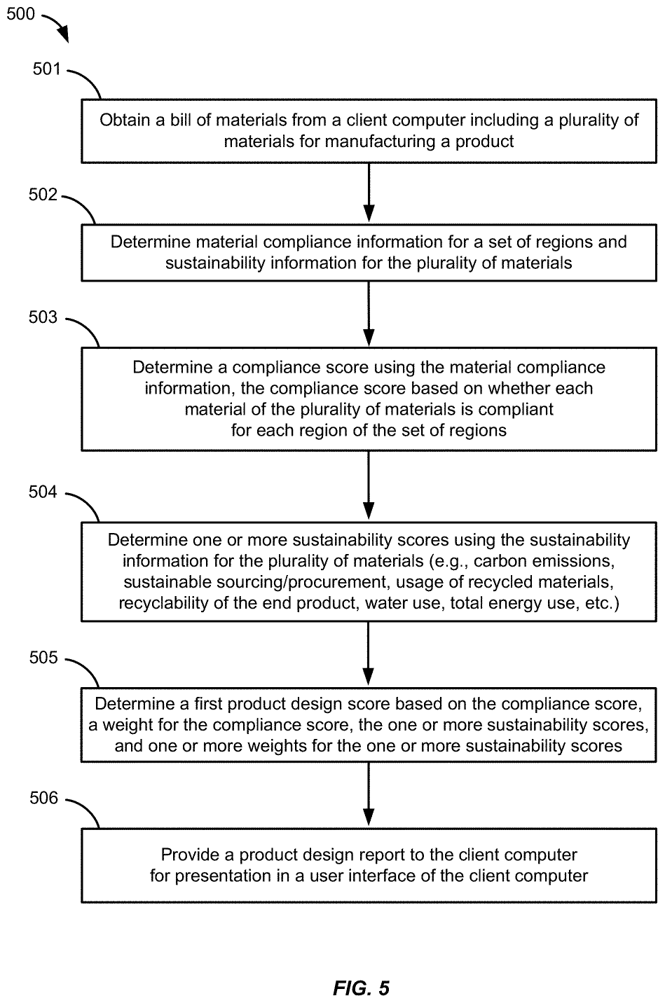

FIG. 5 shows a flowchart 500 of a method for determining a product design score, according to an embodiment. The method may be implemented by a product design system as described herein.

At 501, the method obtains a bill of materials from a client computer including a plurality of materials for manufacturing a product.

At 502, the method determines material compliance information for a set of regions and sustainability information for the plurality of materials.

At 503, the method determines a compliance score using the material compliance information, the compliance score based on whether each material of the plurality of materials is compliant for each region of the set of regions

At 504, the method determines one or more sustainability scores using the sustainability information for the plurality of materials (e.g., carbon emissions, sustainable sourcing/procurement, usage of recycled materials, recyclability of the end product, water use, total energy use, etc.).

At 505, the method determines a first product design score based on the compliance score, a weight for the compliance score, the one or more sustainability scores, and one or more weights for the one or more sustainability scores.

At 506, the method provides a product design report to the client computer for presentation in a user interface of the client computer. The product design report includes the plurality of materials, a compliance status for each of the plurality of materials, and the product design score.

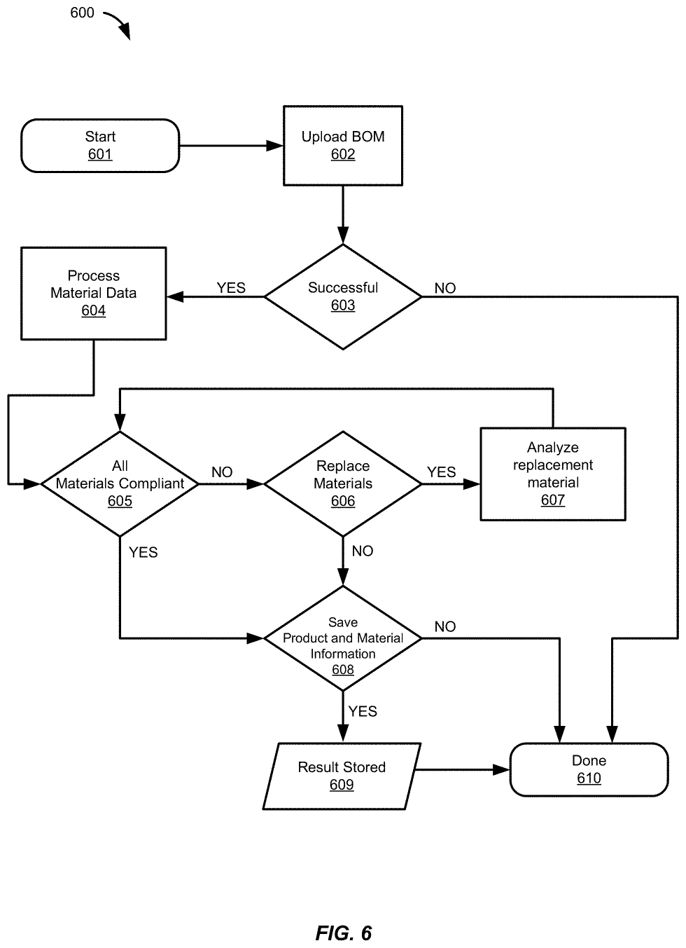

FIG. 6 shows a flowchart 600 of a process for determining compliance of a bill of materials and replacing materials, according to an embodiment. The process may be performed by a product design system, as described herein. The process starts at 601, when a user uploads a bill of materials (BOM) at 602 to the product design system. At 603, the product design system determines whether the upload was successful or not. Success may be based on whether the complete BOM information was received and whether it was in a proper format. If the upload was not successful, the process is done (i.e., finished), at 610. If the upload was successful, the process continues to process the material data at 604. Processing of the material data may include one or more of generating an environmental compliance report listing the non-compliant materials in different countries/state where the product will be manufactured or sold, determining a product design score based on compliance information and sustainability information, performing a cost-benefit analysis, determining the market share impact based on environmentally conscious segments of the market being converted, and estimating risk and financial losses as a result of fines or penalties due to non-compliant materials, as described herein.

At 605, the product design system determines whether all of the materials are complaint. If not all of the materials are complaint (NO) then the product design system determines whether to replace materials at 606. For instance, the user may select an “edit” button to replace materials as discussed above with respect to FIGS. 2, 3, and 4. If the product design system determines to replace materials (YES) at 606, then the product design system may analyze the replacement material at 607 and then determine whether all materials are compliant at 605. In some embodiments, the product design system may also return to step 604 and process the materials data. When all materials are compliant at 605 or if the product design system determines to not replace materials at 605, then the product design system may determine whether to save (i.e., store) the product and material information at 608. If the product design system determines to store the information (YES) then the results are stored at 609. If not, then the process is done at 610.

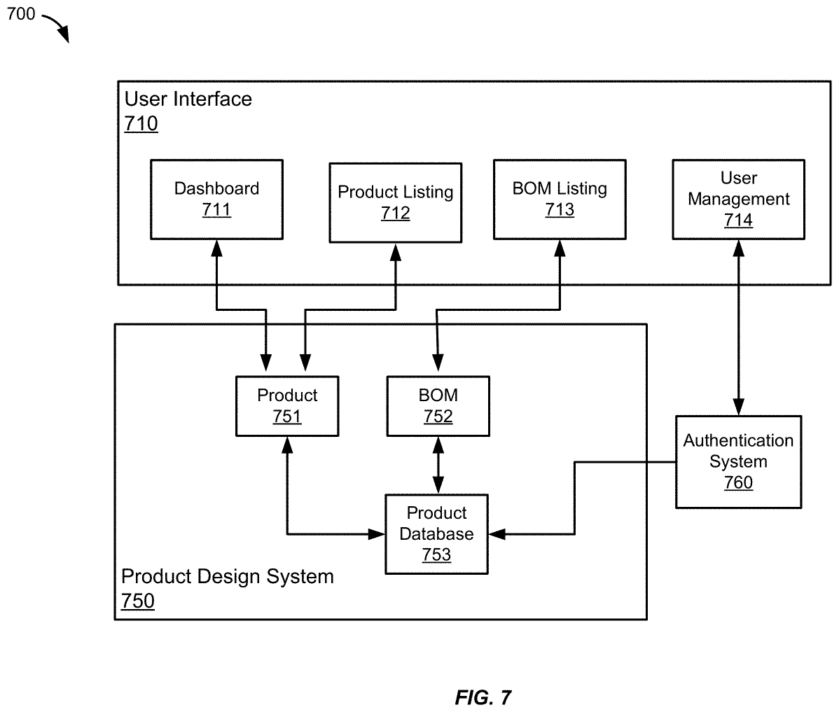

FIG. 7 shows a diagram 700 of components of a product design system 750 and a user interface 710 for the product design system, according to an embodiment. The user interface includes a dashboard 711, a product listing 712, a bill of materials (BOM) listing 713, and user management 714. The product design system 750 includes a product database 753, which may include information on a plurality of products 751 and their corresponding bills of material (BOM) 752. The user interface 710 may present the information as described above with respect to FIGS. 2, 3, and 4.

Details on calculating the product design score using parameters and weights are now described. Different parameters and weights may be used in different implementations. Exemplary parameters, scores, and weights for the product design score are shown in the table below:

| | | | Weighted |
|---|---|---|---|
| Parameter | Score | Weight | Score |
| Compliance | 9 | 10 | 0.90 |
| Carbon Emissions | 9 | 20 | 1.80 |
| Sustainable sourcing/procurement-compliance, | 8 | 30 | 2.40 |
| carbon emissions, etc. | | | |
| Usage of recycled material | 7 | 10 | 0.70 |
| Recyclable end product | 9 | 10 | 0.90 |
| Water use | 6 | 10 | 0.60 |
| Total energy use | 9 | 10 | 0.90 |
| Sum | | 100 | 8.20 |
| Product Design Score | | | 8.2 |

The product design score may be calculated as in the equation below:

$$Product Design Score = {\sum }_{i = 1}^{n} \frac{{w}_{i}}{100} \times {s}_{i}$$

where n is number of parameters, w is weight vector assigned to each parameters and s is score vector for the given product. In the example above, there are seven parameters and so n is 7. The weights w may be assigned to the different parameters of the green score (e.g., by a user) depending on industry and/or product requirements. Each of the assigned weights lies between 1 and 100 and the sum of the weights for all of the parameters should sum up to 100. In some embodiments, the value of the weight may represent a percentage, such that a weight of 10 is 10% (e.g., 0.1). The Product Design may also be rounded.

Exemplary techniques for determining the scores of the parameters is described below. In other embodiments the scores for the parameters may be determined in a different manner. Furthermore, the manner of determining the scores may also be set by a user of the Product Design System.

The Compliance parameter may be calculated as the percentage of materials in the BOM that are compliant in the regions that the product will be sold in, divided by 100.

The Carbon Emissions parameter may be configured (e.g., by a user) as an acceptable carbon emission (Use×Emission Factor=emissions) for manufacture, and an average known usage of the product based on the region and the product.

The Sustainable Sourcing and Procurement parameter may be based on all parameters in the list calculated for the supply chain, as far as supplier discoverability goes down the chain (maximum number).

The Usage of Recycled Material parameter may be the percentage of materials in the BOM that are recycled, divided by 100.

Recyclable end product may be calculated using the equation below:

$${\sum }_{i = 1}^{n} \frac{{w}_{i} \times {r}_{i} \times {u}_{i}}{{w}_{i} \times {u}_{i}}$$

where n is the number of materials, w is the vector containing the weight of each material, r is the vector containing the proportion of recyclable content in the material, and u is the vector containing the units used of each material.

The Water Use parameter may be configured (e.g., by a user) an acceptable water usage, and may be calculated based on the percentage by which the acceptable water usage is exceeded.

The Total Energy Use parameter may be configured (e.g., by a user) as an acceptable energy consumption rate and may be calculated based on the percentage by which the acceptable energy consumption rate is exceeded.

In some embodiments, the score may be on a scale of 1 to 10. In other embodiments, another scale may be used (e.g., 0-100, or A, B, C, D, F, etc.).

In addition to the product design score, the product design system may also provide cost-benefit analysis including detailed insights on how the product design may impact sales and revenue by including various factors such as market share impact based on environmentally conscious segments of the market being converted to potential customers, estimated risk and financial losses as a result of fines or penalties due to non-compliant materials. The product design system may also provide detailed compliance reports indicating areas of non-compliance.

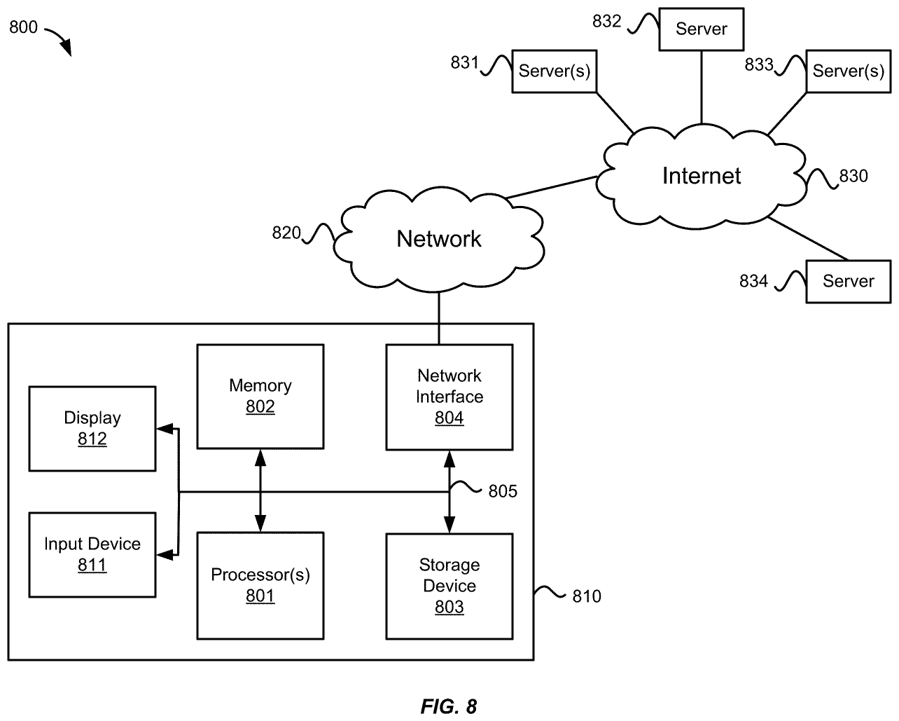

FIG. 8 shows a diagram 800 of hardware of a special purpose computing machine for implementing systems and methods described herein. The following hardware description is merely one example. It is to be understood that a variety of computers topologies may be used to implement the above described techniques. The hardware shown in FIG. 8 may be used to implement the client computer and product design system described herein. For example, the client computer described above may be implemented using the computer system 810 and the product design system may be implemented using one or more of the servers 831-834. In some embodiments, a server computer of the product design system may be implemented using hardware configured similar to the computer system 810.

The computer system 810 includes a bus 805 or other communication mechanism for communicating information, and one or more processor(s) 801 coupled with bus 805 for processing information. The computer system 810 also includes a memory 802 coupled to bus 805 for storing information and instructions to be executed by processor 801, including information and instructions for performing some of the techniques described above, for example. This memory may also be used for storing programs executed by processor(s) 801. Possible implementations of this memory may be, but are not limited to, random access memory (RAM), read only memory (ROM), or both. A storage device 803 is also provided for storing information and instructions. Common forms of storage devices include, for example, a hard drive, a magnetic disk, an optical disk, a CD-ROM, a DVD, a flash or other non-volatile memory, a USB memory card, or any other medium from which a computer can read. Storage device 803 may include source code, binary code, or software files for performing the techniques above, for example. Storage device and memory are both examples of non-transitory computer readable storage mediums.

The computer system 810 may be coupled via bus 805 to a display 812 for displaying information to a computer user. An input device 811 such as a keyboard, touchscreen, and/or mouse is coupled to bus 805 for communicating information and command selections from the user to processor 801. The combination of these components allows the user to communicate with the system. In some systems, bus 805 represents multiple specialized buses, for example.

The computer system also includes a network interface 804 coupled with bus 805. The network interface 804 may provide two-way data communication between computer system 810 and a network 820. The network interface 804 may be a wireless or wired connection, for example. The computer system 810 can send and receive information through the network interface 804 across a local area network, an Intranet, a cellular network, or the Internet, for example. In the Internet example, a browser, for example, may access data and features on backend systems that may reside on multiple different hardware servers 831-834 across the network. The servers 831-834 may be part of a cloud computing environment, for example.

Additional embodiments of the disclosure are described below.

One embodiment provides a computer system comprising one or more processors. The computer system further comprises one or more machine-readable medium coupled to the one or more processors and storing computer program code. The computer program code comprises sets instructions executable by the one or more processors to obtain a bill of materials from a client computer including a plurality of materials for manufacturing a product. The computer program code further comprises sets instructions executable by the one or more processors to determine material compliance information for a set of regions and sustainability information for the plurality of materials. The computer program code further comprises sets instructions executable by the one or more processors to determine a compliance score using the material compliance information. The compliance score based on whether each material of the plurality of materials is compliant for each region of the set of regions. The computer program code further comprises sets instructions executable by the one or more processors to determine one or more sustainability scores using the sustainability information for the plurality of materials. The computer program code further comprises sets instructions executable by the one or more processors to determine a first product design score based on the compliance score, a weight for the compliance score, the one or more sustainability scores, and one or more weights for the one or more sustainability scores. The computer program code further comprises sets instructions executable by the one or more processors to provide a product design report to the client computer for presentation in a user interface of the client computer, the product design report including the plurality of materials, a compliance status for each of the plurality of materials, and the product design score.

In some embodiments, the first material of the plurality of materials is non-compliant in a first geographic region. In such embodiments, the computer program code further comprises sets instructions to generate a notification for presentation in the user interface indicating that the first material is non-compliant in the first region.

In some embodiments, the determination of the first product design score includes applying the weight for the compliance score to the compliance score to obtain a weighted compliance score, applying the one or more weights for the one or more sustainability scores to each corresponding sustainability score of the one or more sustainability scores to obtain one or more weighted sustainability scores, and aggregating the weighted compliance score with the one or more weighted sustainability scores.

In some embodiments, the user interface is configurable to replace a first material of the plurality of materials with a second material, determine a second product design score based on the second material, and update the user interface to include the second material and the second product design score.

In some embodiments, the sustainability information for the plurality of materials includes one or more of carbon emissions information for the plurality of materials, procurement information for the plurality of materials, recycled status for the plurality of materials, recyclability information for the plurality of materials, water use information for the plurality of materials, and total energy use for the plurality of materials.

In some embodiments, the computer program code further comprises sets instructions to generate a cost-benefit analysis report based on the material compliance information for the set of regions, the sustainability information, a cost per unit for the plurality of materials, projected sales, and an estimated market share gain. In such embodiments, the computer program code further comprises sets instructions to provide the product design report to the client computer for presentation in the user interface of the client computer.

In some embodiments, the computer program code further comprises sets instructions to determine a risk and estimated financial losses based on the determination of whether each material of the plurality of materials is compliant for each region of the set of regions. In such embodiments, the computer program code further comprises sets instructions to provide the risk and the estimated financial losses to the client computer for presentation in the user interface of the client computer.

Another embodiment provides one or more non-transitory computer-readable medium storing computer program code. The computer program code comprises sets of instructions to obtain a bill of materials from a client computer including a plurality of materials for manufacturing a product. The computer program code further comprises sets of instructions to determine material compliance information for a set of regions and sustainability information for the plurality of materials. The computer program code further comprises sets of instructions to determine a compliance score using the material compliance information. The compliance score based on whether each material of the plurality of materials is compliant for each region of the set of regions. The computer program code further comprises sets of instructions to determine one or more sustainability scores using the sustainability information for the plurality of materials. The computer program code further comprises sets of instructions to determine a first product design score based on the compliance score, a weight for the compliance score, the one or more sustainability scores, and one or more weights for the one or more sustainability scores. The computer program code further comprises sets of instructions to provide a product design report to the client computer for presentation in a user interface of the client computer, the product design report including the plurality of materials, a compliance status for each of the plurality of materials, and the product design score.

In some embodiments, the first material of the plurality of materials is non-compliant in a first geographic region and the computer program code further comprises sets instructions to generate a notification for presentation in the user interface indicating that the first material is non-compliant in the first region.

In some embodiments, wherein the determination of the first product design score includes applying the weight for the compliance score to the compliance score to obtain a weighted compliance score, applying the one or more weights for the one or more sustainability scores to each corresponding sustainability score of the one or more sustainability scores to obtain one or more weighted sustainability scores, and aggregating the weighted compliance score with the one or more weighted sustainability scores.

In some embodiments, the user interface is configurable to replace a first material of the plurality of materials with a second material, determine a second product design score based on the second material, and update the user interface to include the second material and the second product design score.

In some embodiments, the sustainability information for the plurality of materials includes one or more of carbon emissions information for the plurality of materials, procurement information for the plurality of materials, recycled status for the plurality of materials, recyclability information for the plurality of materials, water use information for the plurality of materials, and total energy use for the plurality of materials.

In some embodiments, the computer program code further comprises sets instructions to generate a cost-benefit analysis report based on the material compliance information for the set of regions, the sustainability information, a cost per unit for the plurality of materials, projected sales, and an estimated market share gain. In such embodiments, the computer program code further comprises sets instructions to provide the product design report to the client computer for presentation in the user interface of the client computer.

In some embodiments, the computer program code further comprises sets instructions to determine a risk and estimated financial losses based on the determination of whether each material of the plurality of materials is compliant for each region of the set of regions. In such embodiments, the computer program code further comprises sets instructions to provide the risk and the estimated financial losses to the client computer for presentation in the user interface of the client computer.

Another embodiment provides a computer-implemented method. The method comprises obtaining a bill of materials from a client computer including a plurality of materials for manufacturing a product. The method further comprises determining material compliance information for a set of regions and sustainability information for the plurality of materials. The method further comprises determining a compliance score using the material compliance information. The compliance score based on whether each material of the plurality of materials is compliant for each region of the set of regions. The method further comprises determining one or more sustainability scores using the sustainability information for the plurality of materials. The method further comprises determining a first product design score based on the compliance score, a weight for the compliance score, the one or more sustainability scores, and one or more weights for the one or more sustainability scores. The method further comprises providing a product design report to the client computer for presentation in a user interface of the client computer, the product design report including the plurality of materials, a compliance status for each of the plurality of materials, and the product design score.

In some embodiments, the first material of the plurality of materials is non-compliant in a first geographic region and the method further comprises generating a notification for presentation in the user interface indicating that the first material is non-compliant in the first region.

In some embodiments, wherein the determination of the first product design score includes applying the weight for the compliance score to the compliance score to obtain a weighted compliance score, applying the one or more weights for the one or more sustainability scores to each corresponding sustainability score of the one or more sustainability scores to obtain one or more weighted sustainability scores, and aggregating the weighted compliance score with the one or more weighted sustainability scores.

In some embodiments, the user interface is configurable to replace a first material of the plurality of materials with a second material, determine a second product design score based on the second material, and update the user interface to include the second material and the second product design score.

In some embodiments, the sustainability information for the plurality of materials includes one or more of carbon emissions information for the plurality of materials, procurement information for the plurality of materials, recycled status for the plurality of materials, recyclability information for the plurality of materials, water use information for the plurality of materials, and total energy use for the plurality of materials.

In some embodiments, the method further comprises generating a cost-benefit analysis report based on the material compliance information for the set of regions, the sustainability information, a cost per unit for the plurality of materials, projected sales, and an estimated market share gain. In such embodiments, the method further comprises providing the product design report to the client computer for presentation in the user interface of the client computer.

In some embodiments, the method further comprises determining a risk and estimated financial losses based on the determination of whether each material of the plurality of materials is compliant for each region of the set of regions. In such embodiments, the method further comprises providing the risk and the estimated financial losses to the client computer for presentation in the user interface of the client computer.

The above description illustrates various embodiments of the present disclosure along with examples of how aspects of the particular embodiments may be implemented. The above examples should not be deemed to be the only embodiments, and are presented to illustrate the flexibility and advantages of the particular embodiments as defined by the following claims. Based on the above disclosure and the following claims, other arrangements, embodiments, implementations, and equivalents may be employed without departing from the scope of the present disclosure as defined by the claims.

What is claimed is:

1. A computer system, comprising:
one or more processors;
one or more machine-readable medium coupled to the one or more processors and storing computer program code comprising sets instructions executable by the one or more processors to:
obtain a bill of materials from a client computer including a plurality of materials for manufacturing a product;
determine material compliance information for a set of regions and sustainability information for the plurality of materials;
determine a compliance score using the material compliance information, the compliance score based on whether each material of the plurality of materials is compliant for each region of the set of regions;
determine one or more sustainability scores using the sustainability information for the plurality of materials;
determine a first product design score based on the compliance score, a weight for the compliance score, the one or more sustainability scores, and one or more weights for the one or more sustainability scores; and
provide a product design report to the client computer for presentation in a user interface of the client computer, the product design report including the plurality of materials, a compliance status for each of the plurality of materials, and the first product design score.

2. The computer storage system of claim 1, wherein the first material of the plurality of materials is non-compliant in a first region, and wherein the computer program code further comprises sets instructions executable by the one or more processors to:
generate a notification for presentation in the user interface indicating that the first material is non-compliant in the first region.

3. The computer storage system of claim 1, wherein the determination of the first product design score includes applying the weight for the compliance score to the compliance score to obtain a weighted compliance score, applying the one or more weights for the one or more sustainability scores to each corresponding sustainability score of the one or more sustainability scores to obtain one or more weighted sustainability scores, and aggregating the weighted compliance score with the one or more weighted sustainability scores.

4. The computer storage system of claim 1, wherein the user interface is configurable to replace a first material of the plurality of materials with a second material, determine a second product design score based on the second material, and update the user interface to include the second material and the second product design score.

5. The computer storage system of claim 1, wherein the sustainability information for the plurality of materials includes one or more of carbon emissions information for the plurality of materials, procurement information for the plurality of materials, recycled status for the plurality of materials, recyclability information for the plurality of materials, water use information for the plurality of materials, and total energy use for the plurality of materials.

6. The computer storage system of claim 1, wherein the computer program code further comprises sets instructions executable by the one or more processors to:
generate a cost-benefit analysis report based on the material compliance information for the set of regions, the sustainability information, a cost per unit for the plurality of materials, projected sales, and an estimated market share gain; and
provide the product design report to the client computer for presentation in the user interface of the client computer.

7. The computer storage system of claim 1, wherein the computer program code further comprises sets instructions executable by the one or more processors to:
determine a risk and estimated financial losses based on the determination of whether each material of the plurality of materials is compliant for each region of the set of regions; and
provide the risk and the estimated financial losses to the client computer for presentation in the user interface of the client computer.

8. One or more non-transitory computer-readable medium storing computer program code comprising sets of instructions to:
obtain a bill of materials from a client computer including a plurality of materials for manufacturing a product;
determine material compliance information for a set of regions and sustainability information for the plurality of materials;
determine a compliance score using the material compliance information, the compliance score based on whether each material of the plurality of materials is compliant for each region of the set of regions;
determine one or more sustainability scores using the sustainability information for the plurality of materials;
determine a first product design score based on the compliance score, a weight for the compliance score, the one or more sustainability scores, and one or more weights for the one or more sustainability scores; and
provide a product design report to the client computer for presentation in a user interface of the client computer, the product design report including the plurality of materials, a compliance status for each of the plurality of materials, and the product design score.

9. The non-transitory computer-readable medium of claim 8, wherein the first material of the plurality of materials is non-compliant in a first geographic region, and wherein the computer program code further comprises sets instructions to:
generate a notification for presentation in the user interface indicating that the first material is non-compliant in the first region.

10. The non-transitory computer-readable medium of claim 8, wherein the determination of the first product design score includes applying the weight for the compliance score to the compliance score to obtain a weighted compliance score, applying the one or more weights for the one or more sustainability scores to each corresponding sustainability score of the one or more sustainability scores to obtain one or more weighted sustainability scores, and aggregating the weighted compliance score with the one or more weighted sustainability scores.

11. The non-transitory computer-readable medium of claim 8, wherein the user interface is configurable to replace a first material of the plurality of materials with a second material, determine a second product design score based on the second material, and update the user interface to include the second material and the second product design score.

12. The non-transitory computer-readable medium of claim 8, wherein the sustainability information for the plurality of materials includes one or more of carbon emissions information for the plurality of materials, procurement information for the plurality of materials, recycled status for the plurality of materials, recyclability information for the plurality of materials, water use information for the plurality of materials, and total energy use for the plurality of materials.

13. The non-transitory computer-readable medium of claim 8, wherein the computer program code further comprises sets instructions to:
generate a cost-benefit analysis report based on the material compliance information for the set of regions, the sustainability information, a cost per unit for the plurality of materials, projected sales, and an estimated market share gain; and
provide the product design report to the client computer for presentation in the user interface of the client computer.

14. The non-transitory computer-readable medium of claim 8, wherein the computer program code further comprises sets instructions to:
determine a risk and estimated financial losses based on the determination of whether each material of the plurality of materials is compliant for each region of the set of regions; and
provide the risk and the estimated financial losses to the client computer for presentation in the user interface of the client computer.

15. A computer-implemented method, comprising:
obtaining a bill of materials from a client computer including a plurality of materials for manufacturing a product;
determining material compliance information for a set of regions and sustainability information for the plurality of materials;
determining a compliance score using the material compliance information, the compliance score based on whether each material of the plurality of materials is compliant for each region of the set of regions;
determining one or more sustainability scores using the sustainability information for the plurality of materials;
determining a first product design score based on the compliance score, a weight for the compliance score, the one or more sustainability scores, and one or more weights for the one or more sustainability scores; and
providing a product design report to the client computer for presentation in a user interface of the client computer, the product design report including the plurality of materials, a compliance status for each of the plurality of materials, and the product design score.

16. The computer-implemented method of claim 15, wherein the first material of the plurality of materials is non-compliant in a first geographic region, and wherein the method further comprises:
generating a notification for presentation in the user interface indicating that the first material is non-compliant in the first region.

17. The computer-implemented method of claim 15, wherein the determination of the first product design score includes applying the weight for the compliance score to the compliance score to obtain a weighted compliance score, applying the one or more weights for the one or more sustainability scores to each corresponding sustainability score of the one or more sustainability scores to obtain one or more weighted sustainability scores, and aggregating the weighted compliance score with the one or more weighted sustainability scores.

18. The computer-implemented method of claim 15, wherein the user interface is configurable to replace a first material of the plurality of materials with a second material, determine a second product design score based on the second material, and update the user interface to include the second material and the second product design score.

19. The computer-implemented method of claim 15, wherein the sustainability information for the plurality of materials includes one or more of carbon emissions information for the plurality of materials, procurement information for the plurality of materials, recycled status for the plurality of materials, recyclability information for the plurality of materials, water use information for the plurality of materials, and total energy use for the plurality of materials.

20. The computer-implemented method of claim 15, further comprising:
generating a cost-benefit analysis report based on the material compliance information for the set of regions, the sustainability information, a cost per unit for the plurality of materials, projected sales, and an estimated market share gain; and
providing the product design report to the client computer for presentation in the user interface of the client computer.
